(19) United States
(12) Patent Application Publication
(10) Pub. No.: US 2008/0286075 A1
(43) Pub. Date: Nov. 20, 2008

(54) Method for producing semiconductor device, and substrate processing apparatus

(75) Inventor: Sadayoshi Horii, Toyamashi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., Tokyo (JP)

(21) Appl. No.: 12/149,988

(22) Filed: May 12, 2008

(30) Foreign Application Priority Data
May 15, 2007 (JP) 2007-129751

(51) Int. Cl. B66C 17/08; H01L 21/00

(52) U.S. Cl. 414/147; 29/25.01

(57) ABSTRACT

Disclosed are a method for producing a semiconductor device and a substrate processing apparatus. The method comprises a step of carrying a substrate into a processing chamber, a step of feeding a material gas into the processing chamber to thereby form a high dielectric constant film on the substrate, a step of carrying the substrate after film formation thereon out of the processing chamber, and a step of feeding an O₃ gas and a Cl-containing gas into the processing chamber under the condition that, when the number of the Cl atoms in the Cl-containing gas is indicated by n, the flow rate of the O₃ gas is at least 2n times the flow rate of the Cl-containing gas, thereby removing the film adhering inside the processing chamber to clean the inside of the processing chamber.

### BACKGROUND OF THE INVENTION

1. Field of the Invention

The present invention relates to a method for producing a semiconductor device that includes a step of removing the film adhering inside the processing chamber, and to a substrate processing apparatus.

2. Related Art

As one process of a method for producing a semiconductor device of the type, there is known a process including a self-cleaning step, or that is, a step of removing (etching) the film adhering inside the processing chamber. For example, for removing the film adhering to the processing chamber in a semiconductor production apparatus for forming a high dielectric constant film that contains hafnium (Hf) or zirconium (Zr), there is known an etching method that comprises introducing a chlorine trifluoride (ClF₃) gas or the like, into the processing chamber for thermochemical reaction of the ClF₃ gas with the Hf or Zr-containing high dielectric constant gas adhering inside the processing chamber, and evaporating away the reaction product. The following formula (1) is a chemical reaction formula of etching a hafnium oxide film (hafnium oxide, HfO₂)

HfO₂+4ClF₃→HfCl₄↑+6F₂↑+O₂↑ (1)

However, the thermochemical reaction of the above formula (1) could not go on when the ambient temperature is not a high temperature of from 300 to 500° C., and the gas may react with the substances constituting the members inside the processing chamber along with the film adhering inside the processing chamber, and, in fact, therefore, the cleaning is difficult. In addition, a metal (M) such as Hf or Zr or a metal oxide thereof may react with a fluorine atom (F) to form a fluoride (MFx, MOxFy) having a low vapor pressure, and therefore there is another problem in that the by-product, fluoride may remain as a cleaning residue. Further, when a fluoride is formed on the surface of HfO₂, then there is still another problem in that the fluoride acts as a barrier film to interfere with the proceeding of the etching reaction. The following formulae (2) and (3) show chemical reaction formulae of formation of by-products of HfO₂.

HfO₂+2ClF₃→HfF₄+Cl₂↑+F₂↑+O₂↑ (2)

HfO₂+4ClF₃→HfOF₂+2Cl₂↑+5F₂↑+½O₂↑ (3)

### SUMMARY OF THE INVENTION

The present invention is to solve the above-mentioned related-art problems, and its objects are to provide a method for producing a semiconductor device that enables continuous etching with no formation of a by-product, fluoride in a low-temperature range, and to provide a substrate processing apparatus.

According to one embodiment of the invention, there is provided a method for producing a semiconductor device comprising the steps of: carrying a substrate into a processing chamber; feeding a material gas into the processing chamber to thereby form a high dielectric constant film on the substrate; carrying the substrate after film formation thereon out of the processing chamber; and feeding an O₃ gas and a Cl-containing gas into the processing chamber under the condition that, when the number of the Cl atoms in the Cl-containing gas is indicated by n, the flow rate of the O₃ gas is at least 2n times the flow rate of the Cl-containing gas, thereby removing the film adhering inside the processing chamber to clean the inside of the processing chamber.

According to another embodiment of the invention, there is provided a method for producing a semiconductor device comprising steps of: carrying a substrate into a processing chamber; feeding a material gas into the processing chamber to thereby form a high dielectric constant film on the substrate; carrying the substrate after film formation thereon out of the processing chamber; and heating the inside of the processing chamber up to a temperature at which, when an O₃ gas is fed into the processing chamber, a part of the O₃ gas may decompose to form oxygen radicals, and feeding the O₃ gas and a Cl-containing gas into the processing chamber thereby removing the film adhering inside the processing chamber to clean the inside of the processing chamber.

According to still another embodiment of the invention, there is provided a substrate processing apparatus comprising: a processing chamber that processes a substrate; a material gas supply line that feeds a material gas for forming a high dielectric constant film, into the processing chamber; a first cleaning gas supply line that feeds an O₃ gas into the processing chamber; a second cleaning gas supply line that feeds a Cl-containing gas into the processing chamber; and a controller that controls the feeding of the O₃ gas and the Cl-containing gas into the processing chamber under the condition that, when the number of the Cl atoms in the Cl-containing gas is indicated by n, the flow rate of the O₃ gas is at least 2n times the flow rate of the Cl-containing gas, thereby removing the film adhering inside the processing chamber to clean the inside of the processing chamber.

The invention comprises a step of feeding an O₃ gas and a gas containing a halogen element but not substantially containing fluorine into a processing chamber to thereby remove the film adhering inside the processing chamber, in which, therefore, a by-product, fluoride is not formed in a low temperature range, and the invention enables continuous etching.

### BRIEF DESCRIPTION OF THE DRAWING

FIG. 1 is an outline view showing a processing furnace in a substrate processing apparatus according to one embodiment of the invention.

In the drawing, 10 is a substrate processing apparatus; 200 is a substrate; 201 is a processing chamber; 232a is a material gas supply duct; 232d is a supply duct; 232f is an ozone gas supply duct; 256 is a main controller.

### DESCRIPTION OF THE PREFERRED EMBODIMENTS

Preferred embodiments of the invention are described below with reference to the drawing.

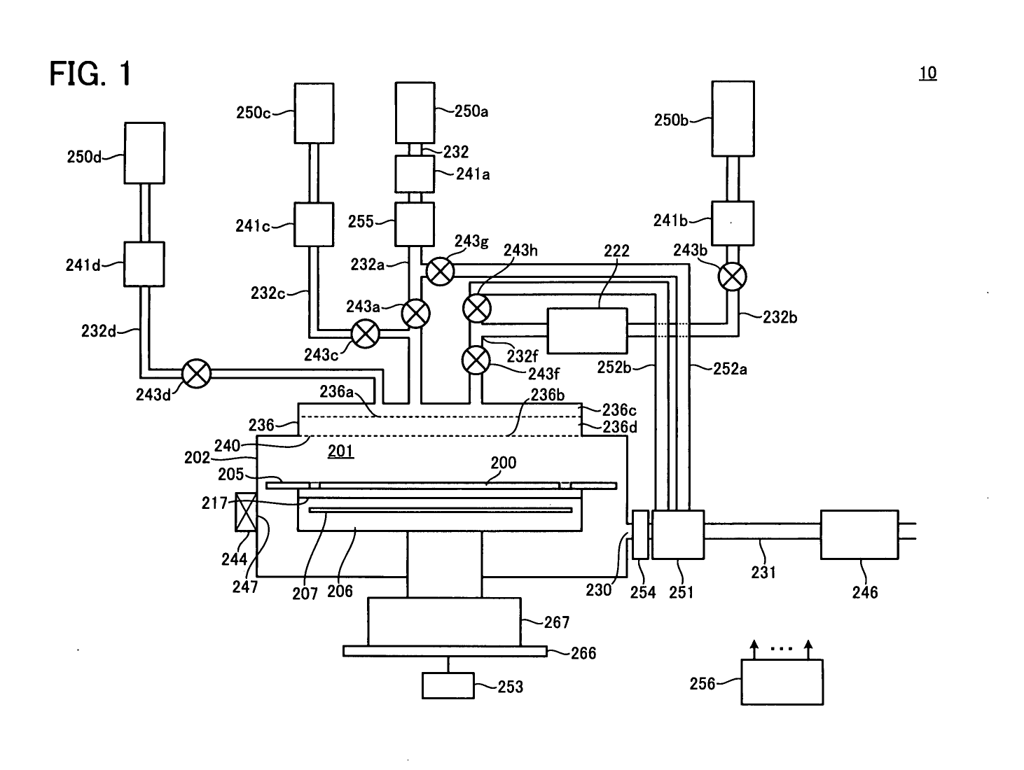

FIG. 1 is an outline view showing one example of a processing furnace of a sheet-fed substrate processing apparatus, for the substrate processing apparatus 10 that includes a self-cleaning method according to an embodiment of the invention.

As shown in FIG. 1, a support stand 206 for supporting the substrate 200 is provided inside the processing chamber 201 formed by the processing container 202. Inside the support stand 206, provided is a heater 207 as a heating mechanism (heating unit), and the substrate 200 set on the susceptor 217 disposed on the support stand 206 is heated by the heater 207. The heater 207 is controlled by a temperature controller 253 as a temperature control member (temperature control unit) so that the temperature of the substrate 200 may be a predetermined temperature. The substrate 200 set on the susceptor 217 is, for example, a semiconductor silicon wafer, a glass substrate or the like.

Outside the processing chamber 201, disposed is a rotary mechanism (rotary unit) 267, and the support stand 206 in the processing chamber 201 is rotated by the rotary mechanism 267, and the substrate 200 on the susceptor 217 is thereby rotated. Outside the processing chamber 201, disposed is an elevator mechanism (elevator unit) 266, and the support stand 206 may be moved up and down inside the processing chamber 201 by the elevator mechanism 266.

Above the processing chamber 201, disposed is a shower head 236 with a large number of holes 240 as gas jet-out orifices, as facing the susceptor 217. The shower head 236 has a disperser 236a for dispersing the gas fed inside it and a shower plate 236b for shower-wise jetting out the gas dispersed by the disperser 236a, into the processing chamber 201. Between the ceiling of the shower head 236 and the disperser 236a, provided is a first buffer space 236c; and between the disperser 236a and the shower plate 236b, provided is a second buffer space 236d.

Outside the processing chamber 201, provided is a material supply source 250a for supplying a liquid material, a liquid material supply duct 232 is connected to the material supply source 250a. The liquid material supply duct 232 is connected to a vaporizer 255 for vaporizing the material, via a liquid flow rate controller (liquid mass flow controller) 241a as a flow rate controlling device (flow rate controlling unit) for controlling the liquid material flow rate. A material gas supply duct 232a is connected to the vaporizer 255. The material is, for example, an organic metal material liquid at room temperature, or that is a liquid organic metal material.

Outside the processing chamber 201, disposed is an inert gas supply source 250c for supplying an inert gas as a non-reactive gas, and an inert gas supply duct 232c is connected to the inert gas supply source 250c. The inert gas supply duct 232c is connected to the material gas supply duct 232a, via a gas flow rate controller (mass flow controller) 241c as a flow rate controlling device (flow rate controlling unit) for controlling the inert gas flow rate, and via a valve 243c. The inert gas is, for example, argon gas (Ar), helium gas (He), nitrogen gas (N₂), etc.

The material gas supply duct 232a acts to feed the material gas vaporized in the vaporizer 255, into the first buffer space 236c of the shower head 236 via a valve 243a, and acts to feed the inert gas from the inert gas supply duct 232c via a valve 243c. Opening and shutting the valve 243a and the valve 243c disposed in the material gas supply duct 232a and the inert gas supply duct 232c, respectively, makes it possible to control the gas supply respectively.

Outside the processing chamber 201, disposed is an ozonizer 222 for forming ozone (O₃) from oxygen (O₂) gas. On the upstream side of the ozonizer 222, disposed is an O₂ gas supply duct 232b. An O₂ gas supply source 250b is connected to the O₂ gas supply duct 232b so as to feed O₂ gas to the ozonizer 222. The O₂ gas supply duct 232b is provided with a gas flow rate controller 241b and a valve 243b for controlling the flow rate of O₂ gas. Opening and shutting the valve 243b makes it possible to control the O₂ gas supply. On the downstream side of the ozonizer 222, disposed is an O₃ gas supply duct 232f. The O₃ gas supply duct 232f is connected to the shower head 236 via a valve 243f, and acts to feed the O₃ gas formed by the ozonizer 222 to the first buffer space 236c of the shower head 236. Opening and shutting the valve 243f disposed in the O₃ gas supply duct 232f makes it possible to control the O₃ gas supply.

Further, outside the processing chamber 201, disposed is a fluorine-free halogen gas supply source 250d for feeding a gas that contains a halogen element but does not substantially contain fluorine; and a supply duct 232d is connected to the fluorine-free halogen gas supply source 250d. The downstream side of the supply duct 232d is connected to the shower head 236 so that a gas that contains a halogen element but does not substantially contain fluorine, for example chlorine (Cl₂) gas may be fed to the first buffer space 236c of the shower head 236. The supply duct 232d is provided with a gas flow rate controller 241d and a valve 243d for controlling the flow rate of the Cl₂ gas. Opening and shutting the valve 243d makes it possible to control the Cl₂ gas supply. As the gas that contains a halogen element but does not substantially contain fluorine, usable is a chlorine-containing gas such as hydrogen chloride (HCl) gas, hypochlorous acid (HClO) gas, dichloromonoxide (Cl₂O) gas, chlorodioxide (ClO₂) gas, carbon tetrachloride (CCl₄) gas or the like, or that is a chlorine atom (chlorine element)-containing gas, in addition to Cl₂ gas.

Preferably, the halogen element-containing gas does not substantially contain a boron (B) element. The reason is as follows:

B may have some negative influences on the step of forming an insulating film, one step of a process for producing a semiconductor device. Specifically, when an insulating film is contaminated with B, then its insulating properties may worsen. As a cleaning gas, it may be taken into consideration to use a Cl-containing gas that contains B, such as boron trichloride (BCl₃); however, in this case, B may remain in the processing chamber and may have some negative influences on the later step of insulating film formation. Accordingly, in the embodiment of the invention in which the processing chamber for forming an insulating film is cleaned, a Cl-containing gas that contains B is not used.

In the lower side wall of the processing container 202, formed is a vent 230; and a vacuum pump 246 as an exhaust device (exhaust unit) and an exhaust pipe 231 communicating with a gas removal system (not shown) are connected to the vent 230. In the exhaust pipe 231, disposed are a pressure controller 254 as a pressure controlling device (pressure controlling unit) for controlling the pressure inside the processing chamber 201, and a material collection trap 251 for collecting the used material. The vent 230 and the exhaust pipe 231 constitute an exhaust system.

On the support stand 206 in the processing chamber 201, disposed is a plate 205 as a baffle plate for rectifying the gas flow fed thereto via the first buffer space 236c, the disperser 236a, the second buffer space 236d and the shower plate 236b of the shower head 236. The plate 205 has a circular (ring) form, and this is disposed around the substrate. The gas fed to the substrate 200 via the shower head 236 flows toward the outer radial direction of the substrate 200, then runs on the plate 205, passes through the space between the plate 205 and the side wall (inner wall) of the processing container 202, and is discharged through the vent 230. In case where the substrate 200 has a part that is not to be covered with a film, for example, the outer peripheral part or the like thereof to be kept uncovered, the inner diameter of the plate 205 may be made smaller than the outer size of the substrate 200 so that the outer peripheral part of the substrate 200 may be thereby covered by it. In this case, in order that the substrate is movable, the plate 205 may be fixed in a site in which the substrate is processed in the processing chamber 201, or a mechanism for moving the plate 205 up and down may be disposed.

In the material gas supply duct 232a, disposed is a material gas bypass (vent tube) 252a that is connected to the material collection trap 251 disposed in the exhaust pipe 231. In the O₃ gas supply duct 232f, disposed is an O₃ gas bypass tube (vent tube) 252b. The bypass tubes 252a and 252b are provided with a valve 234g and a valve 243h, respectively.

In the side wall of the processing container 202 opposite to the vent 230, disposed is a substrate take-in and take-out mouth 247 that is opened and shut by a gate valve 244 as a partitioning valve; and the system is so constituted that a substrate 200 may be taken in and taken out of the processing chamber 201 via the mouth.

The operation of the members that constitute the substrate processing apparatus 10, or that is, the valves 243a to 243h, the flow rate controllers 241a to 241d, the temperature controller 253, the pressure controller 254, the vaporizer 255, the ozonizer 222, the rotary mechanism 267 and the elevator mechanism 266 and the like may be controlled by the main controller 256 as a main controlling device (main controlling unit).

Next described are a method of forming (depositing) a thin film on a substrate and a method of self-cleaning a processing chamber, both as the processing steps in a process of producing a semiconductor device, using the processing furnace having the constitution as in the above-mentioned FIG. 1. As a method of forming a thin film on a substrate, described is an embodiment of forming a thin film of a metal film or a metal oxide film on a substrate, using an organic metal liquid material that is liquid at room temperature, according to a CVD (chemical vapor deposition) method, especially an MOCVD (metal organic chemical vapor deposition) method or an ALD (atomic layer deposition) method. In the following description, the operation of the members that constitute the substrate processing apparatus 10 is controlled by the main controller 256.

When the support stand 206 is let down to the position for substrate transportation and, in that condition, when the gate valve 244 is opened and the substrate take-in and take-out mouth 247 is opened, then a substrate 200 is taken into the processing chamber 201 from a substrate carrier (not shown) (substrate take-in step). After the substrate 200 is taken into the processing chamber 201 and put on an ejector pin (not shown), the gate valve 244 is shut. The support stand 206 is elevated from the substrate take-in position to the upper substrate processing position. During this, the substrate 200 is set on the susceptor 217 from the ejector pin (substrate setting step).

After the support stand 206 has reached the substrate processing position, the substrate 200 is rotated by the rotary mechanism 267. Power is given to the heater 207, and the substrate 200 is uniformly heated up to a predetermined processing temperature (substrate heating step). Simultaneously, the processing chamber 201 is degassed in vacuum by the vacuum pump 246, and is so controlled as to have a predetermined processing pressure (pressure controlling step). During the substrate transportation, the substrate heating and the pressure controlling, the valve 243c disposed in the inert gas supply duct 232c is kept opened all the time, and an inert gas is introduced all the time into the processing chamber 201 from the inert gas supply source 250c. Accordingly, adhesion of particles and metal pollutants to the substrate 200 may be prevented.

When the temperature of the substrate 200 and the pressure inside the processing chamber 201 have reached a predetermined processing temperature and a predetermined processing pressure and have become stable, a material gas is fed into the processing chamber 201. Specifically, the organic metal liquid material as a starting material fed from the material supply source 250a is controlled by the liquid flow rate controller 241a to a controlled flow rate, and fed to the vaporizer 255 and vaporized therein. The valve 243g is shut and the valve 243a is opened, and thus the vaporized material gas passes through the material gas supply duct 232a and is fed onto the substrate 200, via the first buffer space 236c, the disperser 236a, the second buffer space 236d and the shower plate 236b of the shower head 236. Also in this step, the valve 243c is kept opened, and an inert gas is introduced all the time into the processing chamber 201. The material gas and the inert gas are mixed in the material gas supply duct 232a, led to the shower head 236, and shower-wise fed onto the substrate 200 on the susceptor 217, via the first buffer space 236c, the disperser 236a, the second buffer space 236d and the shower plate 236b (material gas supply step). The material gas fed to the substrate 200 is discharged via the exhaust tube 231. The material gas is diluted with the inert gas, and may be therefore more easily stirred.

After the material gas is fed for a predetermined period of time, the valve 243a is shut, and the supply of the material gas to the substrate 200 is stopped. Also in this step, the valve 243c is kept opened, the inert gas supply into the processing chamber 201 is kept as such. The inert gas fed into the processing chamber 201 is discharged through the exhaust tube 231. Accordingly, the processing chamber 201 is purged with an inert gas and the remaining gas in the processing chamber is thereby removed (purging step).

In this state, it is desirable that the valve 243g is opened to discharge the material gas through the bypass tube 252a so as not to stop the material gas supply from the vaporizer 255. Vaporization of the liquid material and stable supply of the vaporized material gas takes a lot of time, and therefore, the bypass flow in the processing chamber 201 is preferably kept as such without stopping the material gas supply from the vaporizer 255. In the preferred embodiment, the material gas may be immediately fed to the substrate 200 by mere gas flow switching in the next material gas supply step.

After the processing chamber 201 has been purged for a predetermined period of time, ozone (O₃) gas as an oxidizing agent is fed into the processing chamber 201. Specifically, the valve 243b is opened, and the oxygen (O₂) gas fed from the oxygen gas supply source 250b passes through the supply duct 232b, and is fed into the ozonizer 222 after its flow rate is controlled by the gas flow rate controller 241b, thereby forming O₃ gas. After the O₃ gas has been formed, the valve 243h is shut and the valve 243f is opened, and the O₃ gas formed by the ozonizer 222 passes through the O₃ gas supply duct 232f, and is shower-wise fed onto the substrate 200 via the first buffer space 236c, the disperser 236a, the second buffer space 236d and the shower plate 236b of the shower head 236 (oxidizing agent supply step). The O₃ gas fed to the substrate 200 is discharged through the exhaust pipe 231. Also in this stage, the valve 243c is kept opened, and an inert gas is kept fed all the time into the processing chamber 201.

After the O₃ gas supply for a predetermined period of time, the valve 342f is shut, and the O₃ gas supply to the substrate 200 is stopped. Also in this stage, the valve 243c is kept opened, and the inert gas supply into the processing chamber is kept as such. The inert gas fed into the processing chamber 201 is discharged through the exhaust pipe 231. Accordingly, the processing chamber 201 is purged with an inert gas, and the remaining gas in the processing chamber 201 is thus removed (purging step).

In this stage, it is desirable that the valve 243h is opened to discharge the O₃ gas through the bypass tube 252b, so as not to stop the O₃ gas supply from the ozonizer 222. A lot of time is taken for stable O₃ gas supply; and therefore, the bypass gas flow around the processing chamber 201 without stopping the O₃ gas supply from the ozonizer 222 enables direct O₃ gas supply to the substrate 200 in the next oxidizing agent supply step merely by switching the flow valves.

After the processing chamber 201 has been purged for a predetermined period of time, the valve 243g is again shut and the valve 243a is opened, and thus the vaporized material gas is fed onto the substrate 200 along with an inert gas thereonto, via the first buffer space 236c, the disperser 236a, the second buffer space 236d and the shower plate 236b of the shower head 236 (material gas supply step).

One cycle comprised of the material gas supply step, the purging step, the oxidizing agent supply step and the purging step mentioned above is repeated plural times for cycle work, thereby forming a thin film having a predetermined thickness on the substrate 200 (thin film forming step).

After the thin film formation on the substrate 200, the rotation of the substrate 200 by the rotary mechanism 267 is stopped, and the processed substrate 200 is then taken out of the processing chamber 201 according to the process opposite to the substrate take-in process (substrate take-out step).

In case where the thin film forming step is attained according to a CVD method, the processing temperature is so controlled as to fall within a temperature range within which the material gas may self-decompose. In this case, the material gas decomposes thermally in the material gas supply step, and a thin film of approximately from a few to dozens of atomic layers is formed on the substrate 200. During this, the substrate 200 is kept at a predetermined temperature while rotated, and therefore a uniform film may be formed on the entire surface of the substrate. In the oxidizing agent supply step, impurities of carbon (C), hydrogen (H) and the like are removed from the thin film of approximately from a few to dozens of atomic layers formed on the substrate 200, by the O₃ gas. Also during this, the substrate 200 is kept at a predetermined temperature while rotated, and therefore, impurities may be rapidly and uniformly removed from the thin film.

In case where the thin film forming step is attained according to an ALD method, the processing temperature is so controlled as to fall within a temperature range within which the material gas does not self-decompose. In this case, the material gas is absorbed by the substrate 200 with no thermal decomposition, in the material gas supply step. During this, the substrate 200 is kept at a predetermined temperature while rotated, and therefore, the material may be uniformly adsorbed by the substrate on the entire surface thereof. In the oxidizing step supply step, the material adsorbed by the substrate 200 reacts with O₃ gas, whereby a thin film of approximately from one to a few atomic layers is formed on the substrate 200. Also during this, the substrate 200 is kept at a predetermined temperature while rotated, and therefore a uniform film may be formed on the entire surface of the substrate. In this stage, impurities such as carbon (C), hydrogen (H) and the like in the thin film may be removed by the O₃ gas.

In the processing furnace of this embodiment, the condition in processing the substrate according to a CVD method may be as follows: For example, when a hafnium oxide film (HfO₂) is formed, the processing temperature (heater temperature) is from 300 to 500° C.; the processing pressure is from 50 to 200 Pa; the supply flow rate of the Hf material (Hf(MMP)₄ (tetrakis(1-methoxy-2-methyl-2-propoxy)-hafnium: Hf(OC(CH₃)₂CH₂OCH₃)₄) is from 0.01 to 0.2 g/min; the supply flow rate of the oxidizing gas (O₃ gas) is from 0.5 to 2 slm.

In the processing furnace of this embodiment, the condition in processing the substrate according to an ALD method may be as follows: For example, when HfO₂ is formed, the processing temperature (heater temperature) is from 150 to 300° C.; the processing pressure is from 10 to 100 Pa; the supply flow rate of the Hf material (TDMAH (tetrakis(dimethylamino)hafnium:Hf(N(CH₃)₂)₄) is from 0.01 to 0.2 g/min; the supply flow rate of the oxidizing gas (O₃ gas) is from 0.5 to 2 slm.

In repeating plural times the thin film formation on the substrate, a film adheres also inside the processing chamber 201, or that is, to the inner wall of the processing chamber 201 (processing container 202) and to the shower head 236, the susceptor 217, the plate 205 and others, like to the surface of the substrate 200. The adhering deposit may more readily peel from the wall surface with the increase in the amount of the deposit, owing to the thermal stress and the stress of the film itself, hereby causing the formation of particles and the like. Accordingly, at the time at which the thickness of the film adhering inside the processing chamber 201 has reached a predetermined level, the processing chamber 201 is self-cleaned for removing it. In this embodiment, ozone (O₃) gas and chlorine (Cl₂) gas are used for the self-cleaning.

The self-cleaning is attained as follows: Power is given to the heater 207, and the area to be cleaned in the processing chamber 201 is uniformly heated up to a predetermined cleaning temperature, for example, falling within a range of from 100 to 150° C. or so (temperature controlling step). Simultaneously, the processing chamber 201 is degassed in vacuum by the vacuum pump 246 and is thereby controlled to have a predetermined cleaning pressure (pressure controlling step). Subsequently, the support stand 206 is rotated by the rotary mechanism 267. The support stand 206 may not be rotated.

Next, a cleaning gas is fed into the processing chamber 201. Specifically, the valve 243b is opened, the oxygen O₂ gas fed from the oxygen gas supply source 250b passes through the supply duct 232b, its flow rate is controlled by the gas flow rate controller 241b, and the gas is then fed to the ozonizer 222, in which O₃ gas as a first cleaning gas is formed. After the O₃ gas has been formed, the valve 243h is shut and the valve 243f is opened, and the O₃ gas formed by the ozonizer 222 is led to pass through the O₃ gas supply duct 232f, and fed to the first buffer space 236c of the shower head 236. In addition, the valve 243d is opened, and the Cl₂ gas fed from the fluorine-free halogen gas supply source 250d as a second cleaning gas is led to pass through the supply duct 232d, then its flow rate is controlled by the gas flow rate controller 241d, and the gas is fed to the first buffer space 236c of the shower head 236. The O₃ gas and the Cl₂ gas thus fed to the first buffer space 236c are mixed in the first buffer space 236c, and then a predetermined amount of the gas mixture is fed to the processing chamber 201 via the disperser 236a, the second buffer space 236d and the shower plate 236b. The O₃ gas and the Cl₂ gas thus fed to the processing chamber 201 run down in the processing chamber 201, and reach the area to be cleaned, and are thereafter discharged out through the exhaust pipe 231. In this stage, O₃ is heated, for example, at from 100 to 150° C. or so, and is thereby decomposed into an oxygen radical (O*) and O₂. This O* reacts with Cl₂ to form chlorine monoxide (ClO*). When this ClO* further meets the ambient O₃, then O₃ is destroyed to give a chlorine radical (Cl*). This Cl* reacts with the deposit adhering inside the processing chamber 201, hafnium oxide (HfO₂), and the deposit is thereby removed (etched) (cleaning step).

After a predetermined cleaning time, the valve 243f and the valve 243d are shut, and the supply of O₃ gas and Cl₂ gas to the processing chamber 201 is stopped. Next, an inert gas is fed from the inert gas supply source 250c to the processing chamber 201, and is discharged through the exhaust pipe 231. Accordingly, the processing chamber 201 is purged for a predetermined period of time, and the remaining gas is thereby discharged (purging step). In that manner, the self-cleaning is finished.

In the processing furnace in this embodiment, the condition in self-cleaning the inside of the processing chamber 201 may be as follows: For example, when HfO₂ is to be cleaned off, the cleaning temperature, or that is, the temperature inside the processing chamber is from 100 to 150° C., the heater temperature is from 300 to 500° C., the cleaning pressure, or that is, the pressure inside the processing chamber is from 50 to 5000 Pa, the first cleaning gas (O₃ gas) supply rate is from 0.5 to 2 μm, the second cleaning gas (Cl₂ gas) supply rate is from 10 to 1000 sccm.

For protecting the susceptor 217 in self-cleaning, a cover substrate 50 having the same diameter as that of the substrate may be inserted through the substrate take-in and take-out mouth 247, before cleaning, and put on the susceptor 217 to cover the surface of the susceptor 217. During film formation, since the substrate 200 exists on the susceptor 217, the film adhering to the susceptor 217 is almost in the part except the substrate-positioning region on the susceptor 217, and therefore it may be considered that only a minor film may adhere in the substrate-positioning region. Accordingly, it is desirable that the substrate-positioning region in the susceptor 217 is protected with the cover substrate 50 of alumina or the like.

Next described is the mechanism of etching reaction in the above-mentioned self-cleaning process.

In the invention, the mechanism of ozone layer depletion by freon gas is specifically noted, and a method of adding O₃ to a halogen compound to thereby etch a metal compound of hafnium (Hf) or zirconium (Zr) is disclosed.

The mechanism of ozone layer depletion by freon gas is described with reference to the following formulae.

First, as in the following formula (4), when freon gas is exposed to UV rays and when Cl* liberated from the freon gas reacts with O₃, then it gives ClO* and O₂.

Cl*+O₃→ClO*+O₂↑ (4)

As in the following formula (5), when ClO* meets the ambient O₃, then it further depletes O₃ to generate Cl*.

ClO*.+O₃→Cl*+2O₂↑ (5)

Cl* returns back to the cycle of the above formula (4), causing chain reaction to further deplete the ozone layer. On the other hand, an example of etching reaction of HfO₂ with a conventional halogen compound is shown in the formula (1). More concretely, as in the following formula (6), chlorine trifluoride (ClF₃) is thermally decomposed into Cl* and a fluorine radical (F*), and these react with HfO₂.

HfO₂+4ClF₃→HfO₂+4Cl*+12F*→HfCl₄↑+6F₂↑+O₂↑ (6)

In the chemical reaction of the above formula (6), the key point of the etching reaction is how efficiently Cl* could be formed. Accordingly, the present inventors tried etching of HfO₂ through introduction of Cl₂ gas in a high-temperature atmosphere at about 400° C., but etching reaction could not occur. This may be because the Cl₂ gas would be stable and could not generate Cl* at about 400° C.

For efficiently generating Cl*, use of O₃ is effective. An example of using Cl₂ and O₃ is described herein. O₃ is decomposed into O* and O₂ when heated in a low temperature range, or that is, at about 100 to 150° C. As in the following formula (7), this O* reacts with Cl₂ to form ClO*. The cleaning temperature is described in detail. When the cleaning temperature is lower than 100° C., then O₃ could hardly decompose. The half value period of O₃ is shorter at a higher temperature, and at 100 to 150° C., the decomposition efficiency of O₃ is good. Accordingly, the cleaning temperature is preferably from 100 to 150° C. Therefore, it may be considered that, within a temperature range of from 100 to 150° C., O₃ may be decomposed efficiently within a few seconds.

2O₃+Cl₂→2O*+2O₂+Cl₂→2ClO*+2O₂↑ (7)

As in the following formula (8), when ClO* further meet the ambient O₃, then the O₃ is depleted to generate Cl*.

ClO*+O₃→Cl*+2O₂↑ (8)

Further as in the following formula (9), Cl* in the above formula (8) is reacted with HfO₂.

HfO₂+4Cl*→HfCl₄↑+O₂↑ (9)

As in the above formula (9), the reaction of Cl* with HfO₂ enables self-cleaning even at a low temperature of from 100 to 150° C. or so. As using the gas substantially free from fluorine, the etching reaction may be continued with no formation of a by-product, fluoride.

In this, when O₃ gas and Cl₂ gas are supplied, then they react with each other according to the above-mentioned formulae (7) and (8), and therefore, two O₃'s are consumed against one Cl₂, two O₃'s are consumed against the formed two ClO*'s and two Cl*'s are produced. In other words, in order that the O₃ molecule and the Cl₂ molecule and the formed ClO* are reacted to produce Cl* without overs and shorts, one Cl₂ is required against four O₃'s. Theoretically, therefore, the consumption efficiency is as follows: O₃:Cl₂=4:1. However, O₃ may decompose during transportation, and therefore, it is desirable that a safety coefficient is applied to the above and the flow rate ratio is to be O₃:Cl₂=50:1. Thus, it is desirable that the amount of O₃ is excessive over the necessary amount for the stoichiometric reaction. The excessive supply of O₃ gas secures the reactions of formulae (7) and (8), whereby Cl* may be efficiently formed. Specifically, the flow rate ratio O₃:Cl₂ is preferably from 4:1 to 50:1.

In case where O₃ and hydrogen chloride (HCl) are used, one Cl* is given against two O₃'s and one HCl. In case where O₃ and carbon tetrachloride (CCl₄) are used, four Cl*'s is given against eight O₃'s and one CCl₄. In other words, the theoretical consumption efficiency is to be O₃:Cl-containing gas=2n:1 (in which n indicates the number of Cl atoms in the Cl-containing gas). Accordingly, in order to secure the reactions of formulae (7) and (8) to efficiently product Cl*, the flow rate of the O₃ gas is preferably at least 2n times the flow rate of the Cl-containing gas when the number of the Cl atoms in the Cl-containing gas is indicated by n.

In the above embodiment, the processing chamber is heated for cleaning it; but plasma may be used in place of heating. However, use of plasma has some disadvantages in that (1) the plasma source installation increases the process cost, (2) for remote plasma, the active species is inactivated in the processing chamber, and (3) for direct plasma, the members in the processing chamber are etched and deteriorated and the like.

In this embodiment, used is Cl₂ gas as one example. Apart from it, however, any other Cl-containing gas substantially free from fluorine (Cl-containing gas such as HCl, HClO, Cl₂O, ClO₂, CCl₄) may also be used.

Such a Cl-containing gas substantially free from fluorine (F) is used for the cleaning gas, and this is because of the following reasons.

The volatility of the fluoride and the chloride to be formed in cleaning by the use of a F-containing gas or a Cl-containing gas is as follows, at room temperature: SiF₄ (g)>SiCl₄ (l)>HfCl₄ (s)>HfF₄ (s). Accordingly, in case where an F-containing gas is used as a cleaning gas, SiF₄ is readily volatile but HfF₄ is relatively hardly volatile. In other words, HfF₄ is difficult to remove. On the other hand, the volatile level of SiCl₄ and HfCl₄ is the intermediate between the above two. Accordingly, in case where a processing chamber for forming a hafnium silicate (HfSiOx) film is cleaned, it is considered that use of a Cl-containing gas may be preferred to use of an F-containing gas.

Apart from the Cl-containing gas, also usable are a Br-containing gas and an I-containing gas, which contain an element of the same group. When these elements are compared with each other as their simple substances, Br₂ is liquid at room temperature, 12 is solid at room temperature, and Cl₂ is gaseous at room temperature; and therefore, use of Cl₂ is preferred as it is easy to use.

From the Clarke number, Cl atoms are the richest, and industrial use of Cl₂ is inexpensive.

The above embodiment is for demonstrating a method of forming HfO₂ and a method of cleaning a processing chamber. Not limited to it, the invention is applicable to all other Hf-containing films such as HfSiOx films, etc.

For HfSiOx films, the chemical reaction to form Cl* is the same as that in the cleaning process for HfO₂ film; but the etching reaction with Cl* differs from that for cleaning of HfO₂ film. This is because the HfSiOx film comprises not only HfSiO₄ but also HfO₂ and SiO₂ as mixed therein.

Accordingly, the reaction of HfSiOx film and Cl* is as follows:

SiO₂+4Cl*→SiCl₄↑+O₂↑ (10)

HfO₂+4Cl*→HfCl₄↑+O₂↑ (11)

HfSiO₄+8Cl*→HfCl₄↑+SiCl₄↑+2O₂↑ (12)

The invention is applicable not only to Hf-containing films alone but also all other zirconium-containing films such as zirconium oxide film (ZrO₂), zirconium silicate film, etc. Further, the invention is applicable to any other high dielectric constant films that the above.

In the substrate processing apparatus of the above embodiment, deposits adhere not only inside the processing chamber but also inside the shower head. Accordingly, not only the inside of the processing chamber but also the inside of the shower head must be cleaned. Therefore, in the above embodiment, both O₃ gas and Cl₂ gas are fed into the processing chamber via the shower head, in order that Cl* could be formed also inside the shower head. Contrary to this, a different method may be employed, which comprises feeding any one of O₃ gas and Cl₂ gas directly to the processing chamber not via the shower head; but in this method, Cl* is not formed in the shower head, and therefore the inside of the shower head could not be cleaned.

A preheating source may be disposed in the supply duct 232f, the supply duct 232a, the supply duct 232c and the supply duct 232d from the downstream side of the ozonizer 222, the vaporizer 255, the gas flow rate controller 241c and the gas flow rate controller 241d, respectively, to the shower head, to thereby preheat the gas running therethrough; and according to this, the treatment of forming a thin film on the substrate and the treatment of self-cleaning the inside of the processing chamber may be efficiently attained.

Not limited to the sheet-fed apparatus of the above embodiment, the invention is also applicable to any other vertical batch-type apparatus.

As described in detail with reference to its preferred embodiments, the invention is applicable to a method for producing a semiconductor device that includes a step of removing the films adhering inside the processing chamber; and the invention does not form a by-product, fluoride at low temperatures, and secures continuous etching.

As claimed in the claims stated below, the invention includes the following embodiments:

(1) A method for producing a semiconductor device comprising the steps of: carrying a substrate into a processing chamber; feeding a material gas into the processing chamber to thereby form a high dielectric constant film on the substrate; carrying the substrate after film formation thereon out of the processing chamber; and feeding an O₃ gas and a Cl-containing gas into the processing chamber under the condition that, when the number of the Cl atoms in the Cl-containing gas is indicated by n, the flow rate of the O₃ gas is at least 2n times the flow rate of the Cl-containing gas, thereby removing the film adhering inside the processing chamber to clean the inside of the processing chamber.

(2) The method for producing a semiconductor device of above (1), wherein in the cleaning step, the flow rate of the O₃ gas is from 2n to 50 times the flow rate of the Cl-containing gas.

(3) The method for producing a semiconductor device of the above (1), wherein the Cl-containing gas is a Cl₂ gas, and in the cleaning step, the flow rate of the O₃ gas is at least 4 times the flow rate of the Cl₂ gas.

(4) The method for producing a semiconductor device of the above (1), wherein the Cl-containing gas is a Cl₂ gas, and in the cleaning step, the flow rate of the O₃ gas is from 4 to 50 times the flow rate of the Cl₂ gas.

(5) The method for producing a semiconductor device of the above (1), wherein the Cl-containing gas is an HCl gas, and in the cleaning step, the flow rate of the O₃ gas is from 2 to 50 times the flow rate of the HCl gas.

(6) The method for producing a semiconductor device of the above (1), wherein the Cl-containing gas is an HCl gas, and in the cleaning step, the flow rate of the O₃ gas is from 2 to 50 times the flow rate of the HCl gas.

(7) The method for producing a semiconductor device of the above (1), wherein the Cl-containing gas is a gas substantially not containing F.

(8) The method for producing a semiconductor device of the above (1), wherein the Cl-containing gas is any of HCl, HClO, Cl₂O, ClO₂ and CCl₄.

(9) The method for producing a semiconductor device of the above (1), wherein a Br-containing gas or an I-containing gas is used in place of the Cl-containing gas.

(10) The method for producing a semiconductor device of the above (1), wherein the Cl-containing gas does not substantially contain B.

(11) A method for producing a semiconductor device comprising steps of: carrying a substrate into a processing chamber; feeding a material gas into the processing chamber to thereby form a high dielectric constant film on the substrate; carrying the substrate after film formation thereon out of the processing chamber; and during heating the inside of the processing chamber up to a temperature at which, when an O₃ gas is fed into the processing chamber, a part of the O₃ gas may decompose to form oxygen radicals, feeding the O₃ gas and a Cl-containing gas into the processing chamber thereby removing the film adhering inside the processing chamber to clean the inside of the processing chamber.

(12) The method for producing a semiconductor device of the above (11), wherein in the cleaning step, the O₃ gas and the Cl-containing gas are fed into the heated processing chamber to attain a chain reaction of thermally decomposing a part of the O₃ gas to form oxygen radicals, reacting the formed oxygen radical with the Cl-containing gas to form chlorine monoxide, and reacting the formed chlorine monoxide with the undecomposed O₃ gas to form chlorine radicals, whereby the film adhering inside the processing chamber is removed by the formed chlorine radicals to clean the inside of the processing chamber.

(13) The method for producing a semiconductor device of the above (11), wherein in the cleaning step, wherein in the cleaning step, the cleaning temperature is from 100 to 150° C.

(14) The method for producing a semiconductor device of the above (11), wherein in the cleaning step, the cleaning pressure is from 50 to 5000 Pa.

(15) The method for producing a semiconductor device of the above (11), wherein the film adhering inside the processing chamber is a hafnium-containing film or a zirconium-containing film.

(16) The method for producing a semiconductor device of the above (11), wherein the film adhering inside the processing chamber is a hafnium oxide film or a zirconium oxide film, and in the cleaning step, the hafnium oxide film or the zirconium oxide film is reacted with the chlorine radical to form a by-product, and the by-product is hafnium chloride or zirconium chloride.

(17) The method for producing a semiconductor device of the above (11), wherein the film adhering inside the processing chamber is a hafnium silicate film, and in the cleaning step, the hafnium silicate film is reacted with the chlorine radical to form a by-product, and the by-product is silicon chloride and hafnium chloride.

(18) The method for producing a semiconductor device of the above (11), wherein in the cleaning step, the O₃ gas and the Cl-containing gas are fed into the processing chamber via a shower head, and the inside of the shower head and the inside of the processing chamber are thereby cleaned.

(19) A substrate processing apparatus comprising:

a processing chamber that processes a substrate; a material gas supply line that feeds a material gas for forming a high dielectric constant film, into the processing chamber; a first cleaning gas supply line that feeds an O₃ gas into the processing chamber; a second cleaning gas supply line that feeds a Cl-containing gas into the processing chamber; and a controller that controls the feeding of the O₃ gas and the Cl-containing gas into the processing chamber under the condition that, when the number of the Cl atoms in the Cl-containing gas is indicated by n, the flow rate of the O₃ gas is at least 2n times the flow rate of the Cl-containing gas, thereby removing the film adhering inside the processing chamber to clean the inside of the processing chamber.

(20) The substrate processing apparatus of the above (19), wherein a preheating source is disposed in the gas supply line.

What is claimed is:

1. A method for producing a semiconductor device comprising the steps of:
carrying a substrate into a processing chamber;
feeding a material gas into the processing chamber to thereby form a high dielectric constant film on the substrate;
carrying the substrate after film formation thereon out of the processing chamber; and
feeding an O₃ gas and a Cl-containing gas into the processing chamber under the condition that, when the number of the Cl atoms in the Cl-containing gas is indicated by n, the flow rate of the O₃ gas is at least 2n times the flow rate of the Cl-containing gas, thereby removing the film adhering inside the processing chamber to clean the inside of the processing chamber.

2. The method for producing a semiconductor device according to claim 1, wherein in the cleaning step, the flow rate of the O₃ gas is from 2n to 50 times the flow rate of the Cl-containing gas.

3. The method for producing a semiconductor device according to claim 1, wherein the Cl-containing gas is a Cl₂ gas, and in the cleaning step, the flow rate of the O₃ gas is at least 4 times the flow rate of the Cl₂ gas.

4. The method for producing a semiconductor device according to claim 1, wherein the Cl-containing gas is a Cl₂ gas, and in the cleaning step, the flow rate of the O₃ gas is from 4 to 50 times the flow rate of the Cl₂ gas.

5. The method for producing a semiconductor device according to claim 1, wherein the Cl-containing gas is an HCl gas, and in the cleaning step, the flow rate of the O₃ gas is at least 2 times the flow rate of the HCl gas.

6. The method for producing a semiconductor device according to claim 1, wherein the Cl-containing gas is an HCl gas, and in the cleaning step, the flow rate of the O₃ gas is from 2 to 50 times the flow rate of the HCl gas.

7. The method for producing a semiconductor device according to claim 1, wherein the Cl-containing gas is a gas substantially not containing F.

8. The method for producing a semiconductor device according to claim 1, wherein the Cl-containing gas is any of HCl, HClO, Cl₂O, ClO₂ and CCl₄.

9. The method for producing a semiconductor device according to claim 1, wherein a Br-containing gas or an I-containing gas is used in place of the Cl-containing gas.

10. The method for producing a semiconductor device according to claim 1, wherein the Cl-containing gas does not substantially contain B.

11. A method for producing a semiconductor device comprising steps of:
carrying a substrate into a processing chamber;
feeding a material gas into the processing chamber to thereby form a high dielectric constant film on the substrate;
carrying the substrate after film formation thereon out of the processing chamber; and
during heating the inside of the processing chamber up to a temperature at which, when an O₃ gas is fed into the processing chamber, a part of the O₃ gas may decompose to form oxygen radicals, feeding the O₃ gas and a Cl-containing gas into the processing chamber thereby removing the film adhering inside the processing chamber to clean the inside of the processing chamber.

12. The method for producing a semiconductor device according to claim 11, wherein in the cleaning step, the O₃ gas and the Cl-containing gas are fed into the heated processing chamber to attain a chain reaction of thermally decomposing a part of the O₃ gas to form oxygen radicals, reacting the formed oxygen radical with the Cl-containing gas to form chlorine monoxide, and reacting the formed chlorine monoxide with the undecomposed O₃ gas to form chlorine radicals, whereby the film adhering inside the processing chamber is removed by the formed chlorine radicals to clean the inside of the processing chamber.

13. The method for producing a semiconductor device according to claim 11, wherein in the cleaning step, the cleaning temperature is from 100 to 150° C.

14. The method for producing a semiconductor device according to claim 11, wherein in the cleaning step, the cleaning pressure is from 50 to 5000 Pa.

15. The method for producing a semiconductor device according to claim 11, wherein the film adhering inside the processing chamber is a hafnium-containing film or a zirconium-containing film.

16. The method for producing a semiconductor device according to claim 11, wherein the film adhering inside the processing chamber is a hafnium oxide film or a zirconium oxide film, and in the cleaning step, the hafnium oxide film or the zirconium oxide film is reacted with the chlorine radical to form a by-product, and the by-product is hafnium chloride or zirconium chloride.

17. The method for producing a semiconductor device according to claim 11, wherein the film adhering inside the processing chamber is a hafnium silicate film, and in the cleaning step, the hafnium silicate film is reacted with the chlorine radical to form a by-product, and the by-product is silicon chloride and hafnium chloride.

18. The method for producing a semiconductor device according to claim 11, wherein in the cleaning step, the O₃ gas and the Cl-containing gas are fed into the processing chamber via a shower head, and the inside of the shower head and the inside of the processing chamber are thereby cleaned.

19. A substrate processing apparatus comprising:
a processing chamber that processes a substrate;
a material gas supply line that feeds a material gas for forming a high dielectric constant film, into the processing chamber;
a first cleaning gas supply line that feeds an O₃ gas into the processing chamber;
a second cleaning gas supply line that feeds a Cl-containing gas into the processing chamber; and
a controller that controls the feeding of the O₃ gas and the Cl-containing gas into the processing chamber under the condition that, when the number of the Cl atoms in the Cl-containing gas is indicated by n, the flow rate of the O₃ gas is at least 2n times the flow rate of the Cl-containing gas, thereby removing the film adhering inside the processing chamber to clean the inside of the processing chamber.

20. The substrate processing apparatus according to claim 19, wherein a preheating source is disposed in the gas supply line.
